(19) United States
(12) Patent Application Publication
(10) Pub. No.: US 2017/0350913 A1
(43) Pub. Date: Dec. 7, 2017

(54) Suspension System

(71) Applicant: Eric Robert Bechhoefer, Cornwall, VT (US)

(72) Inventor: Eric Robert Bechhoefer, Cornwall, VT (US)

(73) Assignee: Green Power Monitoring Systems, Inc., Cornwall, VT (US)

(21) Appl. No.: 15/613,540

(22) Filed: Jun. 5, 2017

Related U.S. Application Data
(60) Provisional application No. 62/345,265, filed on Jun. 3, 2016.

(51) Int. Cl. G01P 1/00; F16F 15/08; B64D 45/00; F16F 1/36; H05K 7/14; F16M 13/02

(52) U.S. Cl. CPC G01P 1/003; H05K 7/1427; F16M 13/02; B64D 45/00; F16F 1/36; F16F 15/08; B64D 2045/0085

(57) ABSTRACT

A suspension system for a health and usage monitoring system including an inertial measurement unit is provided that includes a plurality of elastomer standoffs coupled between an enclosure of the health and usage monitoring system and an electronics board of the health and usage monitoring system thereby allowing for hysteretic damping to reduce vibration and shock experienced by the electronics board and inertial measurement unit.

### RELATED APPLICATION DATA

This application claims priority to U.S. Provisional Application No. 62/345,265 filed on Jun. 3, 2016, and titled “Suspension System,” which is incorporated herein in its entirety.

### FIELD OF THE INVENTION

The present invention generally relates to Health and Usage Monitoring Systems (HUMS) in high vibration environments. In particular, the present invention is directed to a suspension system for HUMS.

### BACKGROUND

Data collected and processed by HUMS can be used to reduce unscheduled maintenance, improve reliability, and facilitate an overall improvement in safety for rotorcraft (helicopters) as well as fixed wing aircraft or ground vehicles.

At a high level, HUMS incorporate sensors to perform: mechanical diagnostics of rotating equipment; rotor track and balance to trim and balance the main rotor (for a helicopter); regime recognition, which determines the state of the aircraft, allowing the HUMS to take acquisitions when the vehicle is in nominal (straight and level) regimes, thereby reducing variance mechanical diagnostics analysis and allowing a damage factor to be applied based on time spent in specific regimes; and structural health monitoring to ensure structural integrity of vehicle frames/bulkheads.

The information collected by the HUMS interrelates to improve performance. For example, regime recognition improves structural health monitoring by allowing correlation of vehicle loads induced by a regime to the measured fatigue by structural health monitoring. Regime recognition is also used by rotor track and balance, in that a helicopter manufacturer establishes flight regimes in which rotor track and balance data is collected, such as, but not limited to, a ground regime, a hover regime, 90 knot regime, and a 120 knot regime.

Additional data collected during operation of the vehicle can include monitoring the performance of the operator (e.g., the pilot or driver of the vehicle). For the helicopter community, this data monitoring is commonly known as helicopter flight data monitoring. Flight data monitoring is the systematic, pro-active, and non-punitive use of digital flight data from routine helicopter operations to improve aviation safety. Flight data monitoring programs assist operators to identify, quantify, assess, and address operational risks, by allowing for the identification of areas of concern and allowing for remedial measures to be taken. The United States Federal Aviation Administration has issued a new rule for Helicopter Air Ambulance, Commercial Helicopter, and Part 91 Helicopter Operations that includes a fixture requirement for flight data monitoring capability in air ambulances.

Both flight data monitoring and regime recognition function require vehicle state data, such as velocities, accelerations, altitude, rates, and time. For HUMS installed on fixed-wing or rotorcraft, this data is usually derived by interfacing with the vehicle's flight control system or altitude heading reference system. This interface requires a significant number of connections (i.e., wires) and a junction box to interface with existing avionics. Additionally, it requires writing custom software to convert the vehicle data into engineering units that can be used by HUMS for, e.g., flight data monitoring and regime recognition analysis.

In a more modern HUMS, to reduce weight and cost of implementing the regime recognition and flight data monitoring function, a HUMS may have an integrated microelectromechanical systems base inertial measurement unit and global positioning system (GPS) receiver. These components allow the HUMS to have the capability of a fully global navigation satellite system and thus fall access to all data related to aircraft velocity, accelerations, heading, altitude, position, and time without the need for connections to other vehicle systems and hardware.

Weight reduction is achieved by removing the additional wiring and the junction box needed to interface with other vehicle systems and hardware, which also reduces reapplication costs by eliminating the need to update or implement an interface control (between the junction box and the vehicle hardware) for different configurations of vehicle hardware.

An advantage of integrating GPS into the inertial measurement unit is that having the GPS update position and velocity states allows for a lower cost microelectromechanical systems base inertial measurement unit to have the performance capabilities of a much more expensive, navigational grade inertial measurement unit.

The environment in which a HUMS is installed can have very high vibration levels. High vibration levels can cause higher than normal failure rates of electronic components included with the HUMS. More problematically, high vibration levels can saturate the accelerometers used in an inertial measurement unit, thus rendering them grossly inaccurate or inoperable. An inertial measurement unit typically has three orthogonally oriented accelerometers, typically with a range of +/−18 g's of acceleration, which are constructed so as to measure vehicle body accelerations at relatively low frequencies (e.g., from about 0 to about 10 Hz).

Rotating equipment on vehicles with HUMS often generate vibration synchronous with a shaft with velocities of 0.5 to 1.0 inches per second. The relationship between shaft rotations in inches per second and g's can be determined by the following:

g=0.0162*shaft rotation in inches per second*frequency Eq. 1

For low frequency shafts, such as a main rotor of a helicopter, which has a frequency of about 5 Hz, a shaft rotation of 1 inch per second generates 0.081 g's of acceleration. However, the input shaft of the main gearbox of a helicopter may have a shaft rate of 268 Hz and include a 22 tooth input pinion, resulting in a gear mesh frequency of 5896 Hz (268 Hz*22) and a 2^{nd} harmonic frequency of 11,792 Hz. Even with moderately low vibration, the main gearbox can cause accelerations of 10 to 100's of g's in the frequency domain. Further exacerbating the vibrations generated in these environments is that the measured, time domain acceleration is the superposition of all shaft, gear, and bearing vibration within a gearbox, which is composed of many shafts and gears.

FIG. 1 is a graph 100 of acceleration versus time and presents 0.02 seconds of data acquired at 97656 samples per second by an accelerometer proximate a HUMS on a commercial rotorcraft during normal operation. As can be seen, the time domain vibration is on the order of +/−100 g's. FIG. 2 is another graph, graph 200, of acceleration versus frequency acquired by an accelerometer proximate a HUMS on a commercial rotorcraft. As can be seen, there are a number of gear mesh tones that individually contribute 8 or more g's of acceleration (at around 3000 Hz, 4100 Hz, 4500 Hz, and 10,000 Hz), In one example, the 14 g's of acceleration at 3000 Hz is from a velocity of 0.3 inches per second. The levels of vibration shown in FIGS. 1 and 2 would reduce the reliability of the HUMS and will saturate the inertial measurement unit, rendering the inertial measurement unit inoperable. In order to improve reliability of the HUMS and to allow for continued operation of the inertial measurement unit, the vibration and shock experienced by the HUMS and the inertial measurement unit needs to be reduced.

It is known that a way to reduced vibration and shock is to shock mount equipment. And while there are examples of avionics that are shock mounted, these mounts are external to the equipment package containing the avionics. External shock mounts, however, add to the weight, complexity, and expense of the installation of avionics. In addition, there is not always sufficient space to externally shock mount the equipment package. Therefore, there is a need for an improved system for reducing excessive vibration and shock experienced by avionics that is light and does not add to the total volume of the equipment package.

### SUMMARY OF THE DISCLOSURE

A suspension system for a vehicle including a health and usage monitoring system subject to shock and vibration is provided including an enclosure attached to the vehicle, an electronics board within the enclosure and having a plurality of health and usage monitoring system components, including an inertial measurement unit, and a plurality of elastomer standoffs coupling the electronics board to the enclosure. Each of the plurality of elastomer standoffs has a loss factor of between about 0.7 and about 1.0 and includes a vibration reducer having a stiffness of between about 20.0 and 30.0 lbs/in, an engagement member having a top mounted to the vibration reducer, and a receiver including an insert having an aperture, wherein the insert is mounted substantially within the vibration reducer.

In another embodiment, an elastomer standoff for reducing vibration experienced by components, including an inertial measurement unit, of a health and usage monitoring system on a vehicle is provided including a vibration reducer having a stiffness of between about 20.0 and 30.0 lbs/in, an engagement member having a top molded into the vibration reducer, the engagement member configured to couple the vibration reducer to an enclosure of the health and usage monitoring system, and a receiver including an insert having an aperture, wherein the insert is mounted substantially within the vibration reducer and configured to couple the vibration reducer to an electronics board of the health and usage monitoring system, wherein the elastomer standoff has a loss factor of between about 0.7 and about 1.0 such that, when the receiver is attached to an electronics board of the health and usage monitoring system and the engagement member is attached to an enclosure of the health and usage monitoring system, energy of vibrations transmitted to the electronics board and the inertial measurement unit is limited to about +/−0.5 g's when the vehicle is in operation.

In another embodiment, a suspension system for a health and usage monitoring system on a vehicle is provided including an enclosure for the health and usage monitoring system, the enclosure attached to the vehicle, an electronics board within the enclosure and including an inertial measurement unit, and a plurality of elastomer standoffs coupling the electronics board to the enclosure, wherein each of the plurality of elastomer standoffs has a loss factor of between about 0.7 and about 1.0. Each of the plurality of elastomer standoffs includes a vibration reducer having a stiffness of between about 20.0 and 30.0 lbs/in, an engagement member having a top mounted to the vibration reducer, and a receiver including an insert having an aperture, wherein the insert is mounted substantially within the vibration reducer, wherein when the receiver of each of the plurality or elastomer standoffs is attached to the electronics board and the engagement member of each of the plurality of elastomer standoffs is attached to the enclosure, energy of vibrations transmitted through the enclosure to the inertial measurement unit is limited to about +/−0.5 g's when the vehicle is in operation.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a graph of acceleration versus time for a prior art HUMS experiencing vibration;

FIG. 2 is a graph of acceleration versus frequency for a prior art HUMS experiencing vibration;

FIG. 3 is a graph of transmissibility versus frequency for a suspension system according to an embodiment of the present invention;

FIG. 4 is a graph of acceleration versus time for a suspension system according to an embodiment of the present invention;

FIG. 5 is a cross-sectional plan view of an elastomer standoff according to an embodiment of the present invention;

FIG. 6 is an exposed plan view of a HUMS system including a suspension system according to an embodiment of the present invention; and

FIG. 6A is a plan view of the HUMS system including a suspension system according to an embodiment of the present invention of FIG. 6 along section 6A-6A.

### DESCRIPTION OF THE DISCLOSURE

A suspension system according to the present disclosure significantly reduces the impact of vibration on HUMS components and diminishes the possibility of inertial measurement unit saturation. In an exemplary embodiment, the suspension system includes an enclosure with a plurality of elastomer standoffs designed and configured to reduce shock and vibration to internal HUMS components. The elastomer standoffs' vibration responses, as disclosed herein, are tuned so that vibration above 20 Hz is attenuated and thus the impact of high vibration levels associated with a gearbox on the HUMS or inertial measurement unit is reduced.

Elastomeric standoffs provide isolation to reduce the transmission of energy from the HUMS packaging (e.g., box, case, or enclosure), which is attached to the aircraft or vehicle, to the electronics board and inertial measurement unit. In an exemplary embodiment, the suspension system has a natural frequency (fₙ) that is dependent on the stiffness of the elastomeric material and the sprung mass of the electronics board on which the inertial measurement unit is mounted. The natural frequency is calculated as:

fₙ=3.13\sqrt{K/W} Eq.

where K is the stiffness of the standoff in pounds per inch and W is the weight of the electronics board.

The elastomeric material of the standoffs is designed to employ hysteretic damping so as to dissipate absorbed energy (i.e., shocks and vibrations) as low-grade heat. A loss factor can be used to quantify the level of hysteretic damping of any given elastomeric material. The loss factor is the ratio of energy dissipated from the system to the energy stored in the system for every oscillation. At resonance, the loss factor, η, is 2ζ, where ζ is the damping ratio. Examples of typical loss factors for elastomeric materials include η=0.4 for Butyl Rubber and η=1.0 for Isodamp® C-1002 (made by Aearo EAR Specialty Composites of Indianapolis, Ind.).

The ability of a system to reduce the impact of vibration and shock, such as the suspension system discussed herein, is determined by the transmissibility of the system, which is the ratio of the energy going into the system to the energy coming out of the system. The transmissibility (T) is determined using Equation 3:

$$T = \vert \frac{{A}_{out}}{{A}_{in}} \vert = \sqrt{\frac{1 + {( 2 ζ {f}_{d} / {f}_{n} )}^{2}}{{[ 1 + {( {f}_{d} / {f}_{n} )}^{2} ]}^{2} + {[ 1 + {( 2 ζ {f}_{d} / {f}_{n} )}^{2} ]}^{2}}} \qquad Eq . 3$$

where Aₒᵤₜ is the energy that goes out of the system, Aₘ is the energy that comes into the system, f_{d} is the driving frequency, and fₐ is the natural frequency.

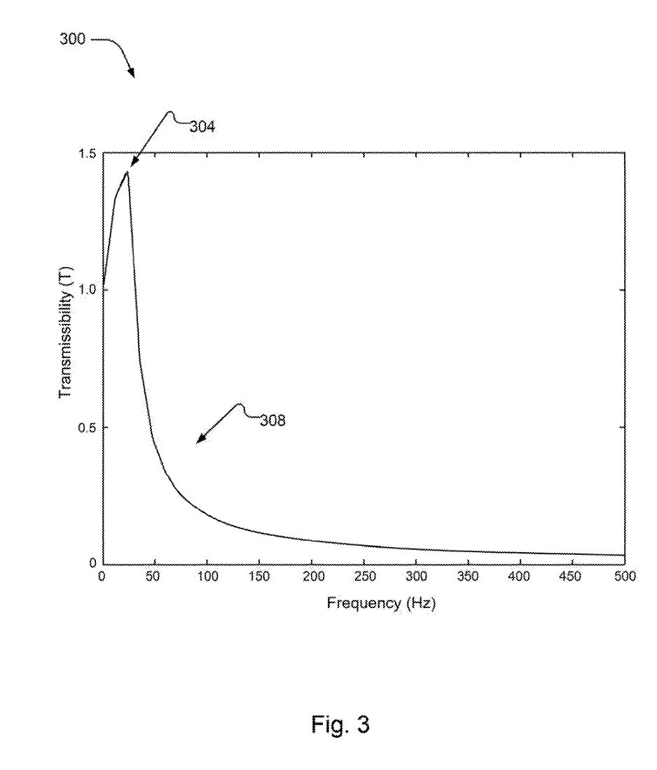

In an exemplary embodiment, an elastomeric standoff designed and configured according to the present disclosure has a stiffness of about 23 lbs/in. Thus, for a HUMS electronics board with weight of about 0.5 lbs, the fₙ, natural frequency would be about 21 Hz. Using an elastomeric material with loss factor of around 0.8 would result in the suspension system having a transfer function 300, which is shown in FIG. 3 on a graph of transmissibility of the suspension system versus frequency of the driving frequency (i.e., the vibrations emanating from the gearbox, etc.). In this scenario, the suspension system would have a bandwidth (3 dB loss, or 50% energy) of about 46 Hz (location 304 on function 300).

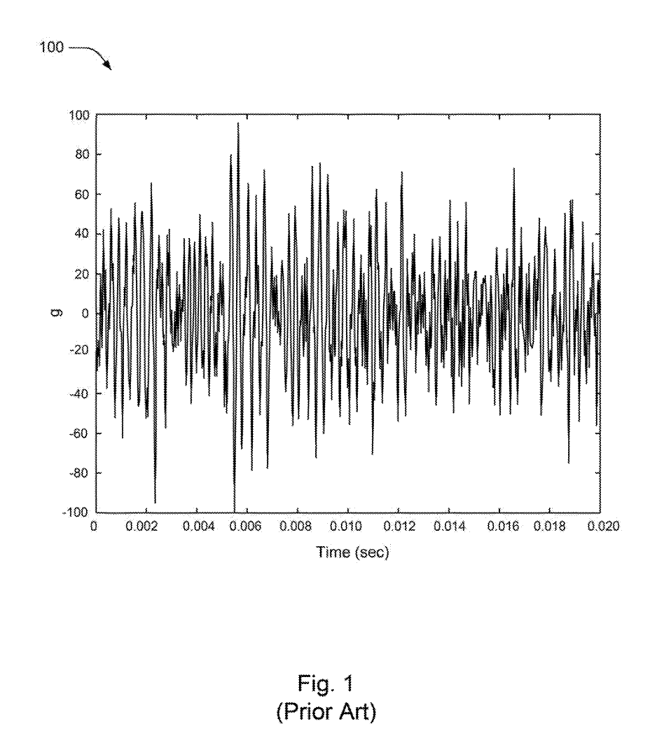

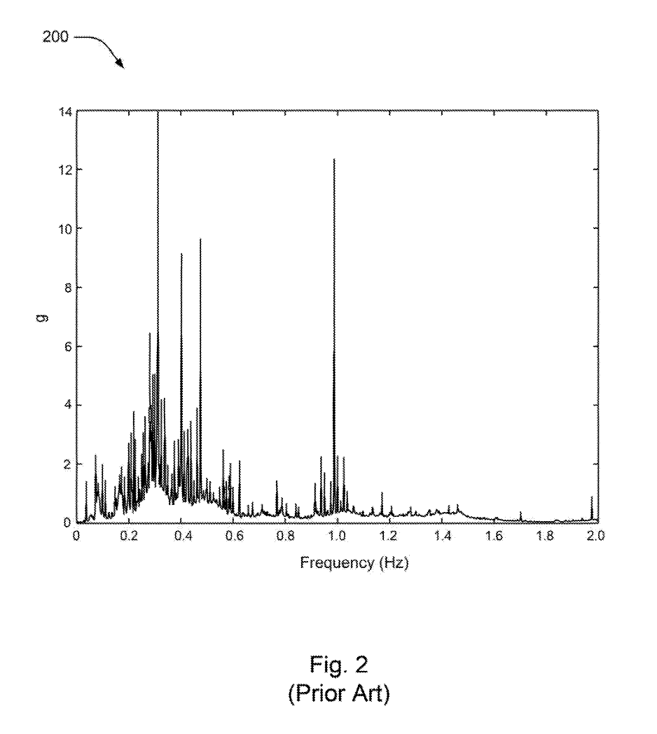

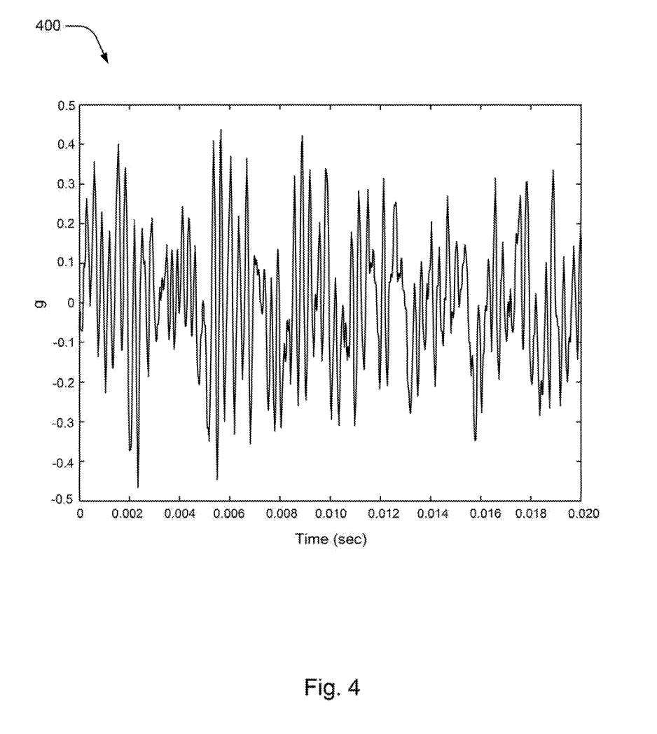

FIG. 4 shows a graph 400 of acceleration versus time and represents the vibration measured on an electronics board in a HUMS, including an inertial measurement unit, on a rotorcraft (at a similar placement as the accelerometer that measured the data used to produce the graph shown in FIG. 1), when including an embodiment of the suspension system discussed herein. As can be seen, the vibration signature transmitted to the HUMS electronics and inertial measurement unit is about +/−0.5 g's, substantially less than the +/−100 g's measured without the suspension system and is well within the acceptable limits of the inertial measurement unit. This low vibration level will enhance the reliability of the HUMS electronics.

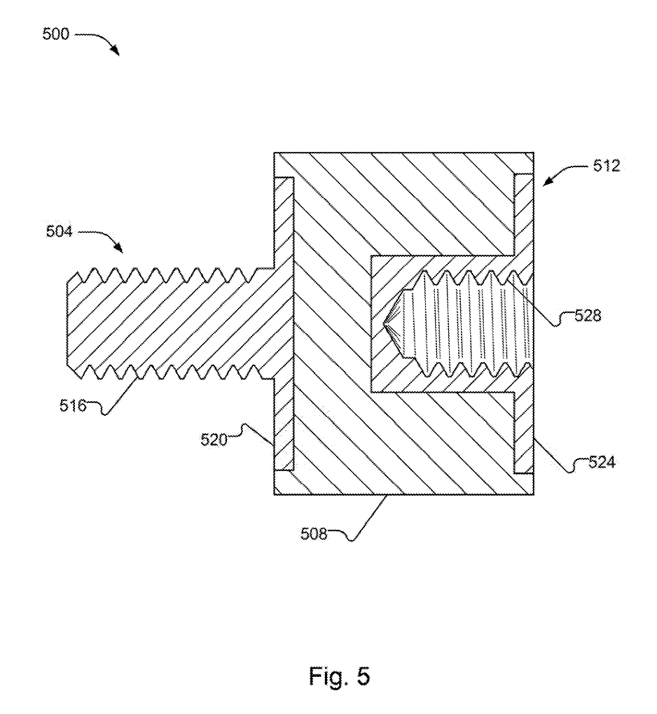

FIG. 5 shows a cross-section of an exemplary elastomer standoff 500 according to an embodiment of the present disclosure. At a high level, the elastomer standoff includes an engagement member 504, a vibration reducer 508, and a receiver 512. Engagement member 504 is designed and configured to couple the elastomer standoff 500 to an enclosure containing a HUMS. As shown in FIG. 5, engagement member 504 has a first end 516 and a top 520. In the embodiment shown in FIG. 5, first end 516 is threaded for fastening to the enclosure; however other types of fastening mechanisms and/or methodologies could be used, such as, but not limited to, snap fit connectors, press rating, etc.

Top 520 is coupled to vibration reducer 508. In an exemplary embodiment, engagement member 504 is coupled to vibration reducer 508 using a molding process wherein top 520 is joined to the bottom of vibration reducer 508.

Vibration reducer 508 is an elastomeric material that has a loss factor of between about 0.7 and 0.9. In an exemplary embodiment, vibration reducer 508 has a loss factor of about 0.8. In another exemplary embodiment, vibration reducer 508 has a stiffness of between about 20.0 and 30.0 lbs/in. In an exemplary embodiment, vibration reducer 508 has a stiffness of about 23.0 lbs./in.

As shown in FIG. 5, vibration reducer 508 is cylindrical in shape; however, other shapes may be used so as to conveniently attach to or be included within the HUMS enclosure.

Receiver 512 is sized and configured to couple elastomer standoff 500 to a HUMS electronics board. In the embodiment shown in FIG. 5, receiver 512 includes an insert 524 including an aperture 528 that has receiving threads. In alternative embodiments, receiver 512 can be configured to receive other types of fasters or connectors. As with engagement member 504, receiver 512 is preferably molded into vibration reducer 508.

Engagement member 504 and receiver 512 are, in an exemplary embodiment, made of a metal, such as aluminum, but other materials could be used such as plastics (e.g., Coolpoly® E2 (a product of Celanese Corporation headquartered in Dallas, Tex.), Polycarbonate). As the elastomer standoff is designed to reduce vibration and shock to the HUMS, creating a durable connection between the HUMS electronics board and the enclosure can be an important consideration depending on the environment into which the HUMS is to be placed.

In an exemplary embodiment of elastomer standoff 500, vibration reducer 508 may have a diameter of about 0.28 inches and have a length (in a direction between the HUMS electronics board and the HUMS enclosure) of about 0.32 inches, with engagement member 504 being a male machine screw having a length of about 0.20 inches and receiver 512 having a female mounting thread depth of about 0.11 inches.

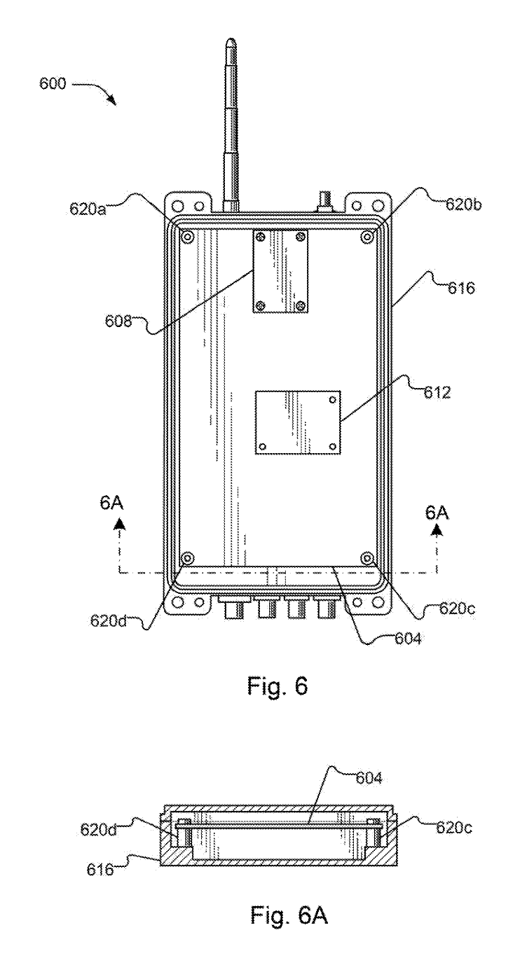

FIGS. 6 and 6A show an exemplary HUMS system 600 that includes an electronics card 604, an inertial measurement unit 608, and a USB 612 within an enclosure 616. Four elastomer standoff's 620 (e.g., 620a, 620b, 620c, and 620d) couple enclosure 616 to electronics card 604, thereby reducing the amount of vibration transmitted from external sources to electronics card 604 and its components.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A suspension system for components subject to shock and vibration, the suspension system comprising:
an enclosure configured to be attached to a vehicle;
an electronics board within the enclosure and having a plurality of health and usage monitoring system components, including an inertial measurement unit; and
a plurality of elastomer standoffs coupling the electronics board to the enclosure, wherein each of the plurality of elastomer standoffs has a loss factor of between about 0.7 and about 1.0, and wherein each of the plurality of elastomer standoffs includes:
a vibration reducer having a stiffness of between about 20 and 30 lbs/in;
an engagement member having a top mounted to the vibration reducer; and
a receiver including an insert having an aperture, wherein the insert is mounted substantially within the vibration reducer.

2. The suspension system of claim 1 wherein each of the plurality of elastomer standoffs has a loss factor of about 0.8.

3. The suspension system of claim 1 wherein the vibration reducer of each of the plurality of elastomer standoffs has a stiffness of about 23 lbs/in.

4. The suspension system of claim 1 wherein the top of the engagement member of each of the plurality of elastomer standoffs is molded into the vibration reducer.

5. The suspension system of claim 1 wherein the receiver of each of the plurality of elastomer standoffs is molded into the vibration reducer.

6. The suspension system of claim 1 wherein is elastomer standoffs couple the electronics board to the enclosure.

7. An elastomer standoff for reducing vibration experienced by components on a vehicle, the elastomer standoff comprising:
a vibration reducer having a stiffness of between about 20 and 30 lbs/in;
an engagement member having a top molded into the vibration reducer, the engagement member configured to couple the vibration reducer to an enclosure of a health and usage monitoring system; and
a receiver including an insert having an aperture, wherein the insert is mounted substantially within the vibration reducer and configured to couple the vibration reducer to an electronics board of a health and usage monitoring system,
wherein the elastomer standoff has a loss factor of between about 0.7 and about 1.0 such that, when the engagement member is attached to an enclosure of a health and usage monitoring system and the receiver is attached to an electronics board within the enclosure, energy from vibrations that are generated by a vehicle in normal operation transmitted to the electronics board is limited to about +/−0.5 g's.

8. The elastomer standoff of claim 7 the elastomer standoff has a loss factor of about 0.8.

9. The elastomer standoff of claim 7 wherein the vibration reducer has a stiffness of about 23 lbs/in.

10. The elastomer standoff of claim 7 wherein the receiver is molded into the vibration reducer.

11. A suspension system for reducing shock and vibrations, the suspension system comprising:
an enclosure for components of a health and usage monitoring system, the enclosure configured to be attached to a vehicle;
an electronics board within the enclosure, the electronics board including an inertial measurement unit; and
a plurality of elastomer standoffs coupling the electronics board to the enclosure, wherein each of the plurality of elastomer standoffs has a loss factor of between about 0.7 and about 1.0, and wherein each of the plurality of elastomer standoffs includes:
a vibration reducer having a stiffness of between about 20 and 30 lbs/in;
an engagement member having a top mounted to the vibration reducer; and
a receiver including an insert having an aperture, wherein the insert is mounted substantially within the vibration reducer,
wherein when the receiver of each of the plurality of elastomer standoffs is attached to the electronics board and the engagement member of each of the plurality of elastomer standoffs is attached to the enclosure, energy from vibrations that are generated by a vehicle in normal operation transmitted through the enclosure to the inertial measurement unit is limited to about +/−0.5 g's.

12. The suspension system of claim 11 wherein each of the plurality of elastomer standoffs has a loss factor of about 0.8.

13. The suspension system of claim 11 wherein the vibration reducer of each of the plurality of elastomer standoffs has a stiffness of about 23 lbs/in.

14. The suspension system of claim 11 wherein the top of the engagement member of each of the plurality of elastomer standoffs is molded into the vibration reducer.

15. The suspension system of claim 11 wherein the receiver of each of the plurality of elastomer standoffs is molded into the vibration reducer.
